(19) United States
(12) Patent Application Publication
(10) Pub. No.: US 2025/0033164 A1
(43) Pub. Date: Jan. 30, 2025

(54) SUBSTRATE PROCESSING APPARATUS AND SUBSTRATE PROCESSING METHOD

(71) Applicant: EBARA CORPORATION, Tokyo (JP)

(72) Inventor: Hirotaka OHASHI, Tokyo (JP)

(21) Appl. No.: 18/716,865

(22) PCT Filed: Nov. 30, 2022
(86) PCT No.: PCT/JP2022/044173

§ 371 Date: Jun. 5, 2024

(30) Foreign Application Priority Data
Dec. 16, 2021 (JP) 2021-204086

(51) Int. Cl. B24B 57/02; B24B 21/00; B24B 21/04; B24B 41/06; B24B 55/06

(52) U.S. Cl. CPC B24B 57/02; B24B 21/002; B24B 21/04; B24B 41/06; B24B 55/06

(57) ABSTRACT

A substrate processing apparatus includes: a substrate holder (5) having a suction holding surface (5a) configured to hold a first surface (2a) of a substrate (W); a processing head (7) arranged to process an outer circumferential portion of the substrate (W); a hydrostatic plate (9) having a fluid support surface (9a) facing the suction holding surface (5a); and a fluid supply line (10) coupled to the hydrostatic plate (9) and configured to supply fluid to a space between the fluid support surface (9a) and a second surface (2b) of the substrate (W). The second surface (2b) is an opposite side of the substrate (W) from the first surface (2a). The fluid support surface (9a) is larger than the suction holding surface (5a).

### TECHNICAL FIELD

The present invention relates to a substrate processing apparatus and a substrate processing method for processing an outer circumferential portion of a substrate, such as a wafer, and more particularly to a substrate processing apparatus and a substrate processing method for processing the outer circumferential portion of the substrate by pressing a processing tool against the outer circumferential portion of the substrate with a processing head.

### BACKGROUND ART

In recent years, devices, such as memory circuits, logic circuits, and image sensors (for example, CMOS sensors), are becoming more highly integrated. In the process of manufacturing these devices, foreign matter, such as fine particles and dust, may adhere to the devices. The foreign matter that has adhered to devices can cause short circuits between wires and can cause circuit malfunctions. Therefore, in order to improve reliability of the devices, it is necessary to clean a wafer on which devices are formed to remove foreign matter from the wafer.

Foreign matter, such as the above-mentioned fine particles and dust, may further adhere to a back surface of the wafer. If such foreign matter adheres to the back surface of the wafer, the wafer may be separated from a stage reference plane of an exposure apparatus, causing the wafer surface to tilt with respect to the stage reference plane. As a result, patterning deviations and focal length deviations may occur. In order to prevent such problems, it is necessary to remove foreign matter from the back surface of the wafer.

Therefore, as shown in FIG. 9, a polishing apparatus has been proposed for removing foreign matter from a wafer. In the polishing apparatus shown in FIG. 9, a wafer W is held on and rotated by a vacuum suction stage 500. A liquid (for example, pure water) is supplied onto a front side 501 of the wafer W. A processing head 505 presses an outer circumferential portion of a back side 502 of the rotating wafer W, so that the processing head 505 slightly scrapes off the outer circumferential portion of the back side 502 of the wafer W. As a result, foreign matter can be removed from the outer circumferential portion of the back side 502 of the wafer W.

Similarly, as shown in FIG. 10, foreign matter can be removed from the outer circumferential portion of the front side 501 of the wafer W by pressing the processing head 505 against the outer circumferential portion of the front side 501 of the wafer W.

### CITATION LIST

### Patent Literature

Patent document 1: Japanese laid-open patent publication No. 2018-139258

### SUMMARY OF INVENTION

### Technical Problem

However, when the processing head 505 is pressed against the outer circumferential portion of the back side 502 of the wafer W, the wafer W is bent upward as shown in FIG. 11. As a result, the outer circumferential portion of the back side 502 of the wafer W may not be properly processed. Furthermore, the liquid that has been supplied to the wafer W impinges on the processing head 505, and the liquid containing polishing debris may bounce onto the front side surface 501 of the wafer W. The polishing debris contained in such liquid may cause contamination of the wafer W and may lower a yield rate.

Similarly, as shown in FIG. 12, when the processing head 505 is polishing the outer circumferential portion of the front side 501 of the wafer W, the liquid containing polishing debris impinges on the processing head 505 and may flow back to the center of the wafer W. Such backflow of the liquid containing the polishing debris may cause contamination of the wafer W and may lower a yield rate.

Therefore, the present invention provides a substrate processing apparatus and a substrate processing method that can prevent a substrate, such as a wafer, from being bent when an outer circumferential portion of the substrate is pressed by a processing head and can further prevent contamination of the substrate due to processing debris.

### Solution to Problem

In an embodiment, there is provided a substrate processing apparatus comprising: a substrate holder having a suction holding surface configured to hold a first surface of a substrate: a processing head arranged to process an outer circumferential portion of the substrate: a hydrostatic plate having a fluid support surface facing the suction holding surface; and a fluid supply line coupled to the hydrostatic plate and configured to supply fluid to a space between the fluid support surface and a second surface of the substrate, the second surface being an opposite side of the substrate from the first surface, the fluid support surface being larger than the suction holding surface . . .

In an embodiment, the processing head is arranged to process an outer circumferential portion of the first surface.

In an embodiment, the processing head is movable so as to process the outer circumferential portion of the first surface and an outer circumferential portion of the second surface.

In an embodiment, the hydrostatic plate has a recess into which the processing head can enter.

In an embodiment, the substrate processing apparatus further comprises a hydrostatic-plate moving device configured to move the hydrostatic plate away from and toward the suction holding surface.

In an embodiment, the substrate processing apparatus further comprises a hydrostatic-plate rotating device configured to rotate the hydrostatic plate.

In an embodiment, the substrate processing apparatus further comprises a cleaning-liquid supply nozzle configured to supply cleaning liquid onto an upper surface of the hydrostatic plate.

In an embodiment, the substrate processing apparatus further comprises: a flow-rate regulation valve configured to regulate a flow rate of the fluid to be supplied to the space; and an operation controller configured to operate the flow-rate regulation valve based on a force applied from the processing head to the outer circumferential portion of the substrate.

In an embodiment, there is provided a substrate processing method comprising: rotating a substrate while holding a first surface of the substrate on a suction holding surface: processing an outer circumferential portion of the substrate by pressing a processing tool against the outer circumferential portion with a processing head; and supplying a fluid to a space between a second surface of the substrate and a fluid support surface of a hydrostatic plate while processing the outer circumferential portion of the substrate, the second surface being an opposite side of the substrate from the first surface, the fluid support surface being larger than the suction holding surface.

In an embodiment, processing the outer circumferential portion of the substrate comprises processing at least an outer circumferential portion of the first surface.

In an embodiment, processing the outer circumferential portion of the substrate comprises processing the outer circumferential portion of the first surface and an outer circumferential portion of the second surface.

In an embodiment, the processing head processes the outer circumferential portion of the second surface while the processing enters a recess formed in the hydrostatic plate.

In an embodiment, the substrate processing method further comprises supplying a cleaning liquid onto an upper surface of the hydrostatic plate after processing of the outer circumferential portion of the substrate.

In an embodiment, the substrate processing method further comprises rotating the hydrostatic plate after processing of the outer circumferential portion of the substrate.

In an embodiment, a flow rate of the fluid to be supplied to the space is adjusted based on a force applied from the processing head to the outer circumferential portion of the substrate.

In an embodiment, the fluid is a liquid.

### Advantageous Effects of Invention

While the processing head presses the processing tool against the outer circumferential portion of the first surface of the substrate, the fluid pressure existing between the fluid support surface of the hydrostatic plate and the second surface of the substrate is applied to the second surface of the substrate. Specifically, the fluid pressure is applied to the substrate from the opposite side of the substrate from the processing head. Such fluid pressure can prevent the substrate from being bent due to the pressing force of the processing head. As a result, the processing head can apply a target pressing force to the substrate and can appropriately process the outer circumferential portion of the first surface of the substrate. Additionally, the hydrostatic plate having the fluid support surface that is larger than the suction holding surface can cover the second surface of the substrate and can protect the second surface from a liquid containing processing debris. As a result, contamination of the substrate can be prevented.

### BRIEF DESCRIPTION OF DRAWINGS

FIG. 1 is a side view showing an example of a substrate;

FIG. 2 is a schematic diagram showing an embodiment of a substrate processing apparatus:

FIG. 3 is a schematic diagram showing another embodiment of the substrate processing apparatus:

FIG. 4 is a plan view of the substrate processing apparatus shown in FIG. 3:

FIG. 5 is a side view showing a processing head when tilted upward by a processing-head tilting device until the processing head faces a second surface of the substrate:

FIG. 6 is a schematic diagram showing the processing head when processing a peripheral edge of the substrate:

FIG. 7 is a schematic diagram showing still another embodiment of the substrate processing apparatus:

FIG. 8 is a schematic diagram showing still another embodiment of the substrate processing apparatus:

FIG. 9 is a schematic diagram showing a conventional example of a polishing apparatus:

FIG. 10 is a schematic diagram showing a conventional example of a polishing apparatus:

FIG. 11 is a schematic diagram showing a conventional example of a polishing apparatus; and

FIG. 12 is a schematic diagram showing a conventional example of a polishing apparatus.

### DESCRIPTION OF EMBODIMENTS

Hereinafter, embodiments of a substrate processing apparatus and a substrate processing method for processing an outer circumferential portion of a substrate, such as a wafer, will be described with reference to the drawings. Specific examples of processing of the outer circumferential portion of the substrate include polishing and cleaning of the outer circumferential portion of the substrate.

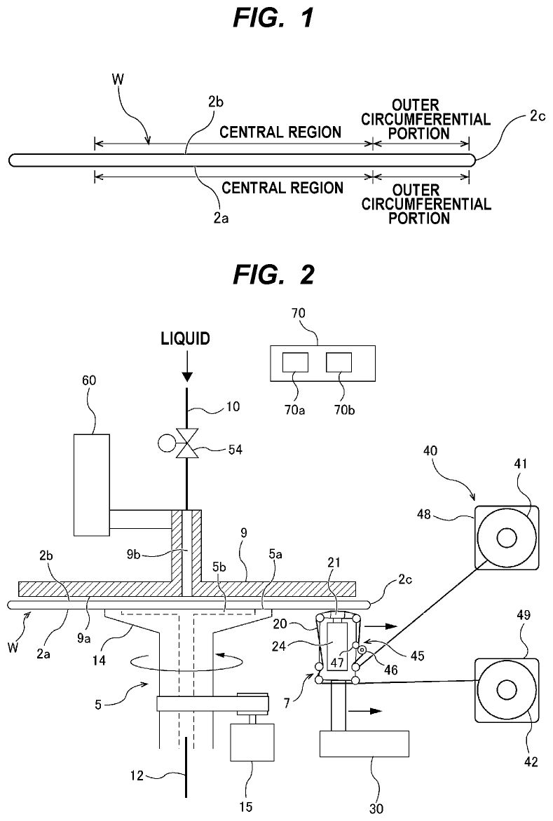

FIG. 1 is a side view showing an example of a substrate. In this embodiment, a first surface 2a of a substrate W is a back surface of the substrate W on which no device is formed or no device is to be formed, i.e., a non-device surface. A second surface 2b of the substrate W opposite to the first surface 2a is a surface on which devices are formed or devices are to be formed, i.e., a device surface. The first surface 2a and the second surface 2b are flat surfaces.

An outer circumferential portion of the first surface 2a of the substrate W is an annular flat surface located around a central region of the first surface 2a of the substrate W. An outer circumferential portion of the second surface 2b of the substrate W is also an annular flat surface located around a central region of the second surface 2b of the substrate W. A peripheral edge 2c of the substrate W is an outermost annular curved surface of the substrate W. The peripheral edge 2c is coupled to both the outer circumferential portion of the first surface 2a and the outer circumferential portion of the second surface 2b. The peripheral edge 2c may be called a bevel portion.

FIG. 2 is a schematic diagram showing an embodiment of a substrate processing apparatus. As shown in FIG. 2, the substrate processing apparatus includes a substrate holder 5 having a suction holding surface 5a configured to hold the first surface 2a of the substrate W, a processing head 7 arranged so as to process the outer circumferential portion of the substrate W, a hydrostatic plate 9 having a fluid support surface 9a facing the suction holding surface 5a, and a fluid supply line 10 for supplying fluid to a space between the fluid support surface 9a and the second surface 2b of the substrate W. In this embodiment, the suction holding surface 5a and the substrate W are circular, and the fluid support surface 9a of the hydrostatic plate 9 is also circular. The size of the fluid support surface 9a may be smaller than or the same as the size of the substrate W.

A vacuum line 12 is coupled to the substrate holder 5. One end of the vacuum line 12 communicates with an opening 5b formed in the suction holding surface 5a, and the other end of the vacuum line 12 is coupled to a vacuum source (for example, a vacuum pump) which is not shown in the drawings. The central region of the first surface 2a of the substrate W is held on the suction holding surface 5a by a vacuum suction force generated within the opening 5b. In this embodiment, the substrate W is supported horizontally by the substrate holder 5 with the first surface 2a facing downward.

The fluid support surface 9a of the hydrostatic plate 9 is located directly above the entire suction holding surface 5a of the substrate holder 5. The fluid support surface 9a is larger than the suction holding surface 5a, and an outermost edge of the fluid support surface 9a is located more radially outward than the suction holding surface 5a. The outer circumferential portion of the first surface 2a and the outer circumferential portion of the second surface 2b (see FIG. 1) are also located more radially outward than the suction holding surface 5a of the substrate holder 5.

The substrate holder 5 includes a substrate stage 14 having the suction holding surface 5a, and a stage motor 15 configured to rotate the substrate stage 14 about the center of the suction holding surface 5a. The stage motor 15 can rotate the substrate W on the suction holding surface 5a. The stage motor 15 may be indirectly coupled to the substrate stage 14 via a belt or the like as shown in FIG. 2, or may be directly coupled to the substrate stage 14.

The processing head 7 is arranged below the outer circumferential portion of the first surface 2a of the substrate W held by the substrate holder 5. The processing head 7 includes a pressing member 21 configured to press a polishing tape 20, which is an example of a processing tool, against the first surface 2a of the substrate W, and an actuator 24 configured to apply a pressing force to the pressing member 21. The actuator 24 pushes the pressing member 21 toward the outer circumferential portion of the first surface 2a of the substrate W, and the pressing member 21 presses the polishing tape 20 from its back side against the outer circumferential portion of the first surface 2a of the substrate W, so that the outer circumferential portion of the first surface 2a is polished (processed).

The substrate processing apparatus further includes a processing-head translation device 30 configured to translate the processing head 7 along the first surface 2a of the substrate W. The processing-head translation device 30 is coupled to the processing head 7. The processing-head translation device 30 is composed of, for example, a combination of a servo motor and a ball screw mechanism, or an air cylinder. While the processing head 7 presses the polishing tape 20 against the outer circumferential portion of the first surface 2a of the substrate W, the processing-head translation device 30 translates the processing head 7 radially outward along the first surface 2a of the substrate W, so that the processing head 7 can process (or polish) the entire outer circumferential portion of the first surface 2a.

The substrate processing apparatus further includes a polishing-tape supply mechanism 40 configured to supply the polishing tape 20 to the processing head 7 and collect the polishing tape 20 from the processing head 7. The polishing-tape supply mechanism 40 includes a tape feeding reel 41 to which one end of the polishing tape 20 is coupled, a tape take-up reel 42 to which the other end of the polishing tape 20 is coupled, and a tape advancing device 45 configured to advance the polishing tape 20 in its longitudinal direction. In this embodiment, the tape advancing device 45 is mounted to the processing head 7. In one embodiment, the tape advancing device 45 may be located remotely from the processing head 7.

The tape advancing device 45 includes a tape advancing roller 46 coupled to a tape advancing motor (not shown), and a nip roller 47 configured to press the polishing tape 20 against the tape advancing roller 46. The polishing tape 20 is sandwiched between the tape advancing roller 46 and the nip roller 47. As the tape advancing motor rotates the tape advancing roller 46, the polishing tape 20 advances in its longitudinal direction. More specifically, the polishing tape 20 advances from the tape feeding reel 41 to the tape take-up reel 42 via the processing head 7.

The tape feeding reel 41 and the tape take-up reel 42 are coupled to reel motors 48 and 49, respectively. These reel motors 48 and 49 apply torques for rotating the tape feeding reel 41 and the tape take-up reel 42 in opposite directions, thereby generating a tension in the polishing tape 20. Positions of the tape feeding reel 41 and the tape take-up reel 42 may be reversed.

In one embodiment, instead of the tape advancing device 45 described above, the reel motors 48 and 49 may function as a tape advancing device. Specifically, when the tape take-up reel 42 is rotated by the reel motor 49, the polishing tape 20 advances from the tape feeding reel 41 to the tape take-up reel 42 via the processing head 7. The torque generated by the reel motor 49 is greater than the torque generated by the reel motor 48, so that the tension is generated in the polishing tape 20.

The hydrostatic plate 9 has a through-hole 9b passing through its center. One end of the through-hole 9b is coupled to a fluid supply line 10, and other end of the through-hole 9b is open in the fluid support surface 9a. The fluid supply line 10 of this embodiment is a liquid supply line that supplies liquid to the space between the fluid support surface 9a and the second surface 2b of the substrate W. An example of the liquid is pure water. The fluid supply line 10 is coupled to a fluid supply source (for example, a liquid supply source, such as a pure-water supply source) which is not shown. A flow-rate regulation valve 54 is attached to the fluid supply line 10, so that a flow rate of the liquid supplied to the hydrostatic plate 9 through the fluid supply line 10 is regulated by the flow-rate regulation valve 54.

The substrate processing apparatus further includes a hydrostatic-plate moving device 60 configured to move the hydrostatic plate 9 away from and toward the suction holding surface 5a. The hydrostatic-plate moving device 60 may be configured to elevate the hydrostatic plate 9 or may be configured to move the hydrostatic plate 9 horizontally. When the substrate W is transported onto the suction holding surface 5a, the hydrostatic-plate moving device 60 moves the hydrostatic plate 9 away from the suction holding surface 5a, so that the substrate W can be held on the suction holding surface 5a. Thereafter, the hydrostatic-plate moving device 60 moves the hydrostatic plate 9 to a position over the suction holding surface 5a.

The outer circumferential portion of the first surface 2a of the substrate W is processed as follows. The substrate W is rotated by the substrate holder 5 while the central region of the first surface 2a of the substrate W is held on the suction holding surface 5a. The hydrostatic plate 9 is independent of the substrate holder 5 and remains stationary. The fluid support surface 9a of the hydrostatic plate 9 faces the second surface 2b of the substrate W and is close to the second surface 2b of the substrate W. A distance between the fluid support surface 9a of the hydrostatic plate 9 and the second surface 2b of the substrate W is in a range of 0.1 mm to 5.0 mm.

The liquid (e.g., pure water) is supplied to the hydrostatic plate 9 through the fluid supply line 10, filling the space between the fluid support surface 9a and the second surface 2b of the substrate W. Pressure of the liquid is applied to the second surface 2b of the substrate W. The liquid flows outward in the space between the fluid support surface 9a and the second surface 2b of the substrate W and flows out of the substrate W. While the processing head 7 presses the polishing tape 20, which is a processing tool, against the outer circumferential portion of the first surface 2a of the substrate W, the processing-head translation device 30 moves the processing head 7 outwardly in the radial direction of the substrate W (see arrow in FIG. 2) until the processing head 7 reaches the peripheral edge 2c of the substrate W. The processing head 7 can bring the polishing tape 20 into contact with the entirety of the outer circumferential portion of the first surface 2a. As a result, the outer circumferential portion of the first surface 2a is processed (or polished).

While the processing head 7 is pressing the polishing tape 20 against the outer circumferential portion of the first surface 2a of the substrate W, the pressure of the liquid existing between the fluid support surface 9a of the hydrostatic plate 9 and the second surface 2b of the substrate W is applied to the second surface 2b of the substrate W. Specifically, the pressure of the liquid is applied to the substrate W from the opposite side of the substrate W from the processing head 7. Such liquid pressure can prevent the substrate W from being bent due to the pressing force of the processing head 7. As a result, the processing head 7 can apply a target pressing force to the substrate W, and can appropriately process the outer circumferential portion of the first surface 2a of the substrate W.

Furthermore, the hydrostatic plate 9 having the fluid support surface 9a larger than the suction holding surface 5a can cover the second surface 2b of the substrate W and can protect the second surface 2b from the liquid containing processing debris. As a result, contamination of the substrate W can be prevented.

In one embodiment, the fluid supply line 10 may be a gas supply line that supplies gas (for example, an inert gas, such as nitrogen gas) to the space between the fluid support surface 9a and the second surface 2b of the substrate W.

The operation of the substrate processing apparatus is controlled by an operation controller 70. The operation controller 70 is electrically coupled to the substrate holder 5, the processing head 7, the polishing-tape supply mechanism 40, the processing-head translation device 30, the hydrostatic-plate moving device 60, and the flow-rate regulation valve 54, so that operations of these elements are controlled by the operation controller 70.

The operation controller 70 is composed of at least one computer. The operation controller 70 includes a memory 70a and an arithmetic device 70b. The memory 70a stores programs therein. The arithmetic device 70b is configured to perform arithmetic operations according to instructions included in the programs. The memory 70a includes a main memory, such as a random access memory (RAM), and an auxiliary memory, such as a hard disk drive (HDD) or a solid state drive (SSD). Examples of the arithmetic device 70b include a CPU (central processing unit) and a GPU (graphic processing unit). However, the specific configuration of the operation controller 70 is not limited to these examples.

The force applied from the processing head 7 to the outer circumferential portion of the first surface 2a of the substrate W can vary depending on conditions, such as a type of substrate W or a processing recipe for the substrate W. As a result, the pressure of the liquid to be applied to the second surface 2b of the substrate W may also vary. Therefore, in one embodiment, the flow rate of the liquid supplied to the space between the fluid support surface 9a and the second surface 2b of the substrate W may be adjusted based on the force applied from the processing head 7 to the outer circumferential portion of the substrate W. More specifically, the operation controller 70 is configured to operate the flow-rate regulation valve 54 based on the force applied from the processing head 7 to the outer circumference portion of the first surface 2a of the substrate W. According to this embodiment, the pressure of the liquid applied to the second surface 2b of the substrate W increases in accordance with the increase in the force applied from the processing head 7 to the outer circumference portion of the substrate W, so that bending of the substrate W can be more reliably prevented.

The force applied from the processing head 7 to the outer circumferential portion of the first surface 2a of the substrate W is generated by the actuator 24 of the processing head 7. The force generated by the actuator 24 can be estimated from a command value of the force to be generated by the actuator 24. For example, if the actuator 24 is composed of an air cylinder, the force generated by the actuator 24 can be estimated from a command value to a pressure regulator that controls the pressure of gas supplied to the air cylinder. In another example, if the actuator 24 is composed of a linear motor or a servo motor, the force generated by the actuator 24 can be estimated from the command value of the electric power to be supplied to the linear motor or servo motor. The force generated by the actuator 24 may be directly measured by a load measuring device, such as a load cell.

The operation controller 70 operates the flow-rate regulation valve 54 based on the estimated value or measured value of the force generated by the actuator 24, so that the pressure of the liquid can cancel the force applied to the first surface 2a of the substrate W. In one embodiment, a plurality of processing heads 7 for polishing the outer circumferential portion of the first surface 2a of the substrate W may be provided.

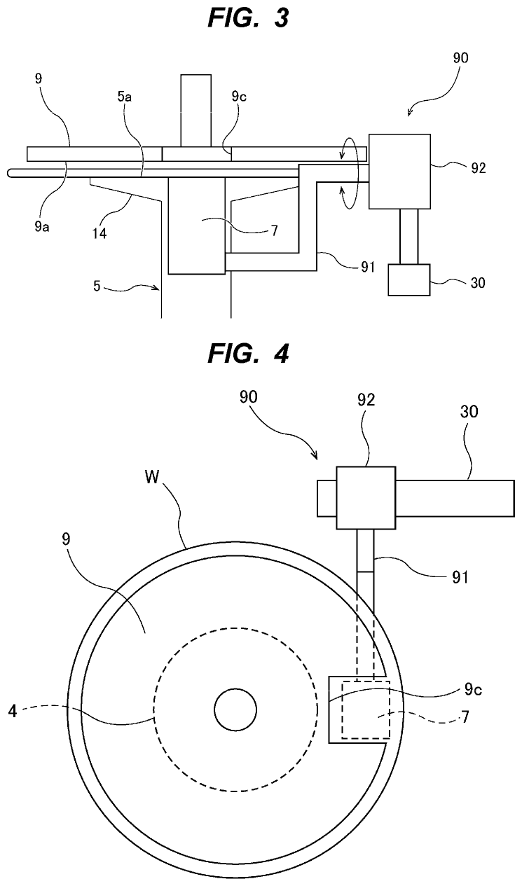

FIG. 3 is a schematic diagram showing another embodiment of the substrate processing apparatus, and is a side view seen from a direction of the polishing-tape supply mechanism 40. FIG. 4 is a plan view of the substrate processing apparatus shown in FIG. 3. In order to facilitate understanding of the structure, illustrations of the polishing-tape supply mechanism 40, the hydrostatic-plate moving device 60, the operation controller 70, etc. are omitted in FIGS. 3 and 4. Configurations of this embodiment, which will not be particularly described, are the same as those of the embodiment described with reference to FIG. 2, and redundant explanations will be omitted.

The substrate processing apparatus of this embodiment includes a processing-head tilting device 90 configured to tilt the processing head 7 with respect to the suction holding surface 5a of the substrate holder 5. This processing-head tilting device 90 includes a crank arm 91 coupled to the processing head 7 and an arm rotating device 92 configured to rotate the crank arm 91. One end of the crank arm 91 is located at substantially the same height as the suction holding surface 5a, and is coupled to the arm rotating device 92. The other end of the crank arm 91 is coupled to the processing head 7. The arm rotating device 92 is coupled to the processing-head translation device 30. Specifically, the processing head 7 is coupled to the processing-head translation device 30 via the processing-head tilting device 90.

When the arm rotating device 92 rotates the crank arm 91, the entire processing head 7 can be tilted with respect to the suction holding surface 5a and the substrate W. It should be noted that the specific configuration of the processing-head tilting device 90 is not limited to the embodiment shown in FIGS. 3 and 4, as long as the processing-head tilting device 90 can tilt the processing head 7 with respect to the suction holding surface 5a and the substrate W.

The hydrostatic plate 9 has a recess 9c into which the processing head 7 can enter. The recess 9c is formed in a periphery of the hydrostatic plate 9, and has a width larger than a width of the processing head 7. A position of the recess 9c corresponds to the position of the processing head 7. In one embodiment, a plurality of processing heads 7 for polishing the outer circumferential portion of the substrate W may be provided. In this case, the hydrostatic plate 9 may have a plurality of recesses 9c corresponding to the plurality of processing heads 7.

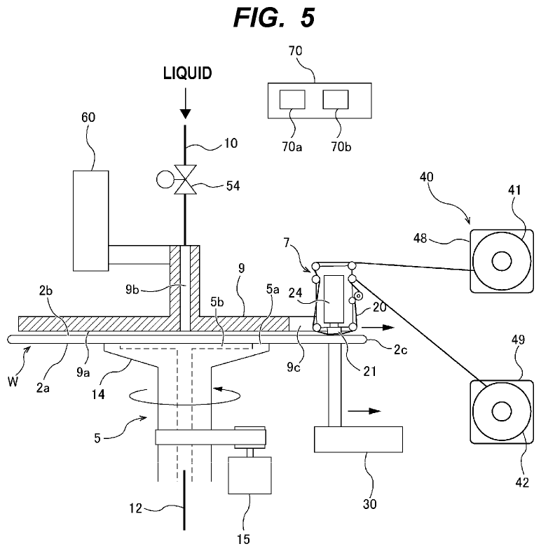

FIG. 5 is a side view showing a state in which the processing head 7 is tilted upward by the processing-head tilting device 90 until the processing head 7 faces the second surface 2b of the substrate W. As shown in FIG. 5, when the processing head 7 faces the second surface 2b of the substrate W, the processing head 7 enters the recess 9c of the hydrostatic plate 9. Therefore, the processing head 7 can process (polish) the outer circumferential portion of the second surface 2b of the substrate W without contacting the hydrostatic plate 9.

The outer circumferential portion of the second surface 2b of the substrate W can be processed in the same manner as the outer circumferential portion of the first surface 2a of the substrate W. Specifically, liquid (e.g., pure water) is supplied to the hydrostatic plate 9 through the fluid supply line 10 to fill the space between the fluid support surface 9a and the second surface 2b of the substrate W. The liquid flows outward in the space between the fluid support surface 9a and the second surface 2b of the substrate W and flows out of the substrate W. The processing head 7 presses the polishing tape 20, which is a processing tool, against the outer circumferential portion of the second surface 2b of the substrate W, while the processing-head translation device 30 moves the processing head 7 outwardly in the radial direction of the substrate W (see arrow in FIG. 5). The processing head 7 can bring the polishing tape 20 into contact with the entirety of the outer circumferential portion of the second surface 2b. As a result, the outer circumferential portion of the second surface 2b is processed (or polished).

While the processing head 7 is pressing the polishing tape 20 against the outer circumferential portion of the second surface 2b of the substrate W, the liquid flows radially outwardly in the space between the fluid support surface 9a of the hydrostatic plate 9 and the second surface 2b of the substrate W. Such liquid flow can reliably prevent processing debris (polishing debris) generated by the contact between the polishing tape 20 and the substrate W from moving toward the center of the substrate W. Therefore, contamination of the second surface 2b of the substrate W due to the processing debris can be prevented.

According to the embodiment shown in FIG. 5, the processing head 7 can process the outer circumferential portions of both the first surface 2a and the second surface 2b of the substrate W. One of the outer circumferential portion of the first surface 2a and the outer circumferential portion of the second surface 2b is processed first, and the other is processed later. When the outer circumferential portion of the first surface 2a is being processed and when the outer circumferential portion of the second surface 2b is being processed, the processing head 7 is moved outwardly in the radial direction of the substrate W by the processing-head translation device 30 until the processing head 7 reaches the peripheral edge 2c of the substrate W.

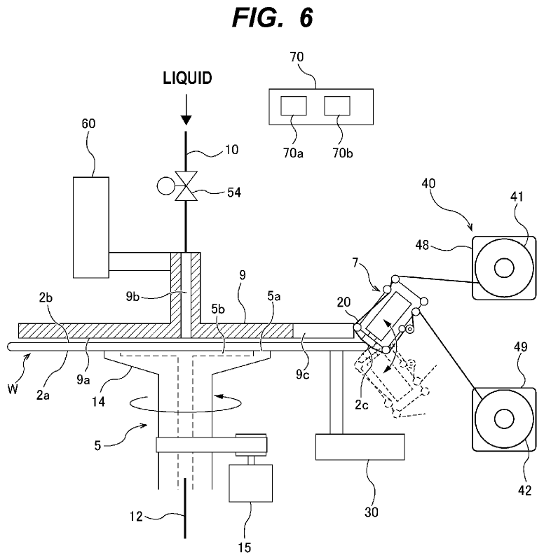

The processing head 7 can further process the peripheral edge 2c of the substrate W. Specifically, as shown in FIG. 6, while the processing head 7 is pressing the polishing tape 20 against the peripheral edge 2c of the rotating substrate W, the processing-head tilting device 90 (see FIGS. 3 and 4) tilts the processing head 7 along the peripheral edge 2c of the substrate W. During polishing of the peripheral edge 2c of the substrate W, the liquid flows radially outward in the space between the fluid support surface 9a of the hydrostatic plate 9 and the second surface 2b of the substrate W, as well as the embodiments described above.

The processing of the peripheral edge 2c of the substrate W may be performed after the processing of either the outer circumferential portion of the first surface 2a or the outer circumferential portion of the second surface 2b is completed. In one embodiment, the outer circumferential portion of the first surface 2a is processed in step 1, the peripheral edge 2c of the substrate W is processed in step 2, and the outer circumferential portion of the second surface 2b is processed in step 3. The processing of the outer circumferential portion of the first surface 2a in the step 1 and the processing of the peripheral edge 2c of the substrate W in the step 2 can be performed continuously without stopping the motion of the processing head 7.

In another embodiment, the outer circumferential portion of the second surface 2b is processed in step 1, the peripheral edge 2c of the substrate W is processed in step 2, and the outer circumferential portion of the first surface 2a is processed in step 3. Also in this case, the processing of the outer circumferential portion of the second surface 2b in the step 1 and the processing of the peripheral edge 2c of the substrate W in the step 2 can be performed continuously without stopping the motion of the processing head 7.

According to the embodiment shown in FIG. 6, the outer circumferential portion of the first surface 2a, the peripheral edge 2c of the substrate W, and the second surface 2b are processed continuously, so that the throughput of processing the substrate W can be improved.

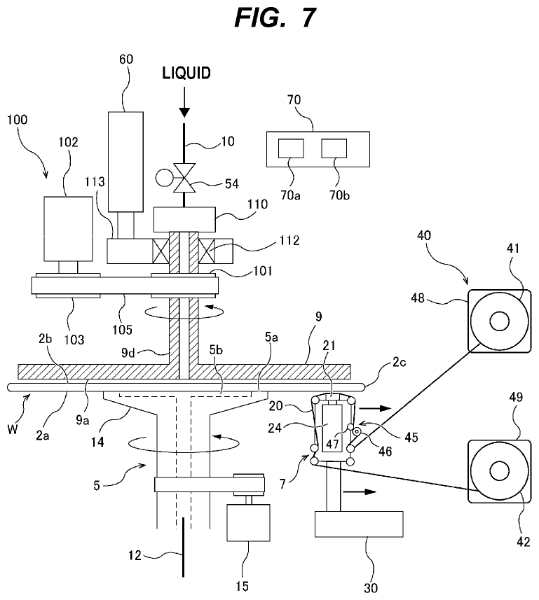

FIG. 7 is a schematic diagram showing still another embodiment of the substrate processing apparatus. Configuration and operation of this embodiment, which are not particularly described, are the same as those of the embodiments described with reference to FIG. 2, and repetitive explanations thereof will be omitted. As shown in FIG. 7, the substrate processing apparatus of this embodiment includes a hydrostatic-plate rotating device 100 configured to rotate the hydrostatic plate 9. This hydrostatic-plate rotating device 100 includes a first pulley 101 fixed to a shaft portion 9d of the hydrostatic plate 9, a plate rotating motor 102, a second pulley 103 fixed to a drive shaft of the plate rotating motor 102, and a belt 105 mounted on the first pulley 101 and the second pulley 103.

The fluid supply line 10 is coupled to a rotary joint 110 fixed to the shaft portion 9d of the hydrostatic plate 9. The shaft portion 9d of the hydrostatic plate 9 is rotatably supported by a bearing 112, which is held by a bearing holder 113. The hydrostatic-plate moving device 60 is coupled to the bearing holder 113.

During processing of the outer circumferential portion (and peripheral edge 2c) of the substrate W, the hydrostatic-plate rotating device 100 does not rotate the hydrostatic plate 9. In other words, the hydrostatic plate 9 remains stationary while the substrate W is being processed. After processing of the substrate W, the hydrostatic-plate rotating device 100 rotates the hydrostatic plate 9, thereby removing the liquid adhering to the hydrostatic plate 9 (particularly the liquid adhering to the upper surface of the hydrostatic plate 9) by centrifugal force. As a result, the hydrostatic plate 9 can be kept clean. The liquid may be supplied from the fluid supply line 10 to the space between the fluid support surface 9a of the hydrostatic plate 9 and the second surface 2b of the substrate W while the hydrostatic plate 9 is rotating.

In one embodiment, the hydrostatic-plate rotating device 100 may include a combination of gears instead of the combination of the first pulley 101, the second pulley 103, and the belt 105.

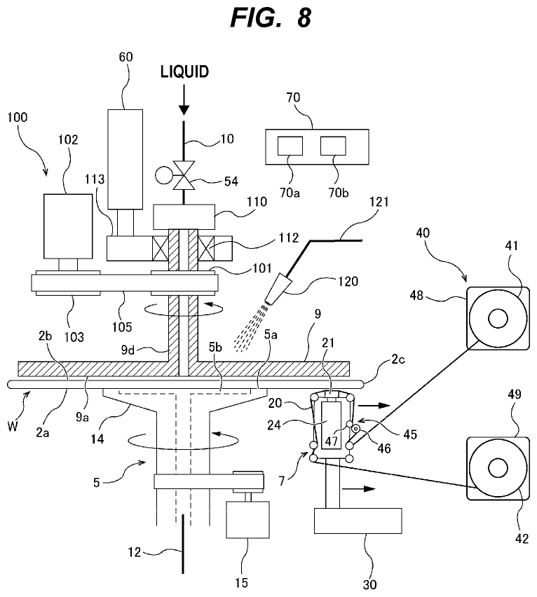

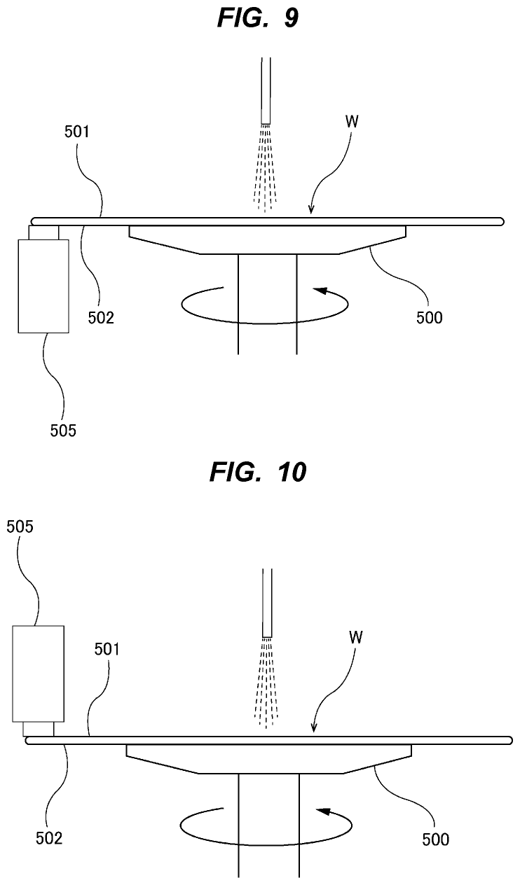

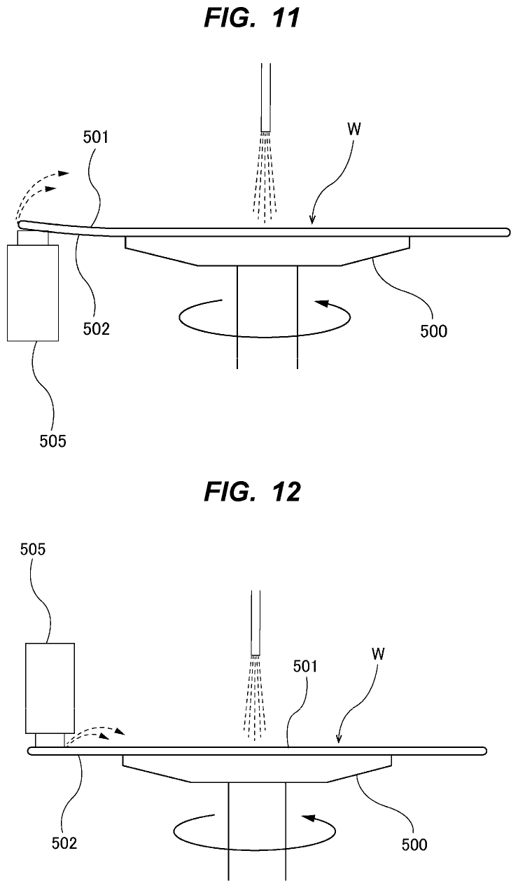

In an embodiment shown in FIG. 8, the substrate processing apparatus may further include a cleaning-liquid supply nozzle 120 configured to supply cleaning liquid to the upper surface of the hydrostatic plate 9. The cleaning-liquid supply nozzle 120 is coupled to a cleaning-liquid supply line 121 and is oriented toward the upper surface of the hydrostatic plate 9. After processing of the outer circumferential portion of the substrate W, the cleaning liquid is supplied onto the upper surface of the hydrostatic plate 9 from the cleaning-liquid supply nozzle 120. An example of the cleaning liquid is pure water. According to the embodiment shown in FIG. 8, the hydrostatic plate 9 can be kept cleaner.

The cleaning liquid may be supplied onto the upper surface of the hydrostatic plate 9 from the cleaning-liquid supply nozzle 120 while the hydrostatic plate 9 is being rotated by the hydrostatic-plate rotating device 100. In one embodiment, while the hydrostatic plate 9 is being rotated by the hydrostatic-plate rotating device 100, the cleaning liquid may be supplied from the cleaning-liquid supply nozzle 120 onto the upper surface of the hydrostatic plate 9, and the liquid may be supplied from the fluid supply line 10 to the space between the fluid support surface 9a of the hydrostatic plate 9 and the second surface 2b of the substrate W.

The embodiments described above can be combined as appropriate. For example, the hydrostatic-plate rotating device 100 shown in FIG. 7 can be combined with the embodiments described with reference to FIGS. 3 to 6. Similarly, the cleaning-liquid supply nozzle 120 shown in FIG. 8 can be combined with the embodiments described with reference to FIGS. 3 to 6.

In each of the embodiments described above, the polishing tape 20 is used as a processing tool, while instead of the polishing tape 20, a whetstone, a cleaning tape, a cleaning brush, a nonwoven tape, a cleaning pad, etc. may be used as the processing tool. Specific examples of the processing of the outer circumferential portion of the substrate W include cleaning of the outer circumferential portion of the substrate W in addition to polishing of the outer circumferential portion of the substrate W.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a substrate processing apparatus and a substrate processing method for processing an outer circumferential portion of a substrate by pressing a processing tool against the outer circumferential portion of the substrate with a processing head.

### REFERENCE SIGNS LIST

2a first surface
2b second surface
2c peripheral edge
5 substrate holder
5a suction holding surface
5b opening
7 processing head
9 hydrostatic plate
9a fluid support surface
9b through-hole
9c recess
9d shaft portion
10 fluid supply line
12 vacuum line
14 substrate stage
15 stage motor
20 polishing tape
21 pressing member
24 actuator
30 processing-head translation device
40 polishing-tape supply mechanism
41 tape feeding reel
42 tape take-up reel
45 tape advancing device
46 tape advancing roller
47 nip roller
48, 49 reel motor
54 flow-rate regulation valve
60 hydrostatic-plate moving device
70 operation controller
70a memory
70b arithmetic device
90 processing-head tilting device
91 crank arm
92 arm rotating device
100 hydrostatic-plate rotating device
101 first pulley
102 plate rotating motor
103 second pulley
105 belt
110 rotary joint
112 bearing
113 bearing holder
120 cleaning-liquid supply nozzle
121 cleaning-liquid supply line
W substrate

1. A substrate processing apparatus comprising:
a substrate holder having a suction holding surface configured to hold a first surface of a substrate;
a processing head arranged to process an outer circumferential portion of the substrate;
a hydrostatic plate having a fluid support surface facing the suction holding surface; and
a fluid supply line coupled to the hydrostatic plate and configured to supply fluid to a space between the fluid support surface and a second surface of the substrate, the second surface being an opposite side of the substrate from the first surface, the fluid support surface being larger than the suction holding surface.

2. The substrate processing apparatus according to claim 1, wherein the processing head is arranged to process an outer circumferential portion of the first surface.

3. The substrate processing apparatus according to claim 2, wherein the processing head is movable so as to process the outer circumferential portion of the first surface and an outer circumferential portion of the second surface.

4. The substrate processing apparatus according to claim 3, wherein the hydrostatic plate has a recess into which the processing head can enter.

5. The substrate processing apparatus according to claim 1, further comprising a hydrostatic-plate moving device configured to move the hydrostatic plate away from and toward the suction holding surface.

6. The substrate processing apparatus according to claim 1, further comprising a hydrostatic-plate rotating device configured to rotate the hydrostatic plate.

7. The substrate processing apparatus according to claim 1, further comprising a cleaning-liquid supply nozzle configured to supply cleaning liquid onto an upper surface of the hydrostatic plate.

8. The substrate processing apparatus according to claim 1, further comprising:
a flow-rate regulation valve configured to regulate a flow rate of the fluid to be supplied to the space; and
an operation controller configured to operate the flow-rate regulation valve based on a force applied from the processing head to the outer circumferential portion of the substrate.

9. A substrate processing method comprising:
rotating a substrate while holding a first surface of the substrate on a suction holding surface;
processing an outer circumferential portion of the substrate by pressing a processing tool against the outer circumferential portion with a processing head; and
supplying a fluid to a space between a second surface of the substrate and a fluid support surface of a hydrostatic plate while processing the outer circumferential portion of the substrate, the second surface being an opposite side of the substrate from the first surface, the fluid support surface being larger than the suction holding surface.

10. The substrate processing method according to claim 9, wherein processing the outer circumferential portion of the substrate comprises processing at least an outer circumferential portion of the first surface.

11. The substrate processing method according to claim 10, wherein processing the outer circumferential portion of the substrate comprises processing the outer circumferential portion of the first surface and an outer circumferential portion of the second surface.

12. The substrate processing method according to claim 11, wherein the processing head processes the outer circumferential portion of the second surface while the processing enters a recess formed in the hydrostatic plate.

13. The substrate processing method according to claim 9, further comprising supplying a cleaning liquid onto an upper surface of the hydrostatic plate after processing of the outer circumferential portion of the substrate.

14. The substrate processing method according to claim 9, further comprising rotating the hydrostatic plate after processing of the outer circumferential portion of the substrate.

15. The substrate processing method according to claim 9, wherein a flow rate of the fluid to be supplied to the space is adjusted based on a force applied from the processing head to the outer circumferential portion of the substrate.

16. The substrate processing method according to claim 9, wherein the fluid is a liquid.
